(19) United States
(12) Patent Application Publication
(10) Pub. No.: US 2009/0184323 A1
(43) Pub. Date: Jul. 23, 2009

(54) THIN FILM TRANSISTOR ARRAY PANEL AND METHOD FOR MANUFACTURING THE SAME

(76) Inventors: Byung-Duk YANG, Yongin-si (KR); Eun-Guk Lee, Yongin-si (KR); Hyang-Shik Kong, Seongnam-si (KR); Kyoung-Tai Han, Suwon-si (KR)

Correspondence Address: Haynes and Boone, LLP;IP Section, 2323 Victory Avenue, SUITE 700, Dallas, TX, 75219, US

(21) Appl. No.: 12/240,707

(22) Filed: Sep. 29, 2008

(30) Foreign Application Priority Data
Jan. 22, 2008 (KR) 10-2008-0006756

(51) Int. Cl. H01L 27/146; H01L 21/28

(52) U.S. Cl. 257/72; 438/70; 257/E27.133; 257/E21.158

(57) ABSTRACT

The present invention relates to a thin film transistor array panel and a method for manufacturing the same. A thin film transistor array panel according to the present invention includes a substrate, a light blocking member formed on the substrate and including a first furrow and a receiving portion, a gate line disposed on the first furrow, a semiconductor layer disposed on the gate line, a source electrode and a drain electrode formed on the semiconductor layer, and a pixel electrode connected to the drain electrode. The source electrode is an extension of the data line.

### CROSS-REFERENCE TO RELATED APPLICATION

This application claims priority to and the benefit of Korean Patent Application No. 10-2008-0006756 filed in the Korean Intellectual Property Office on Jan. 22, 2008, the entire content of which is incorporated herein by reference.

### BACKGROUND OF THE INVENTION

(a) Field of the Invention

The present invention relates to a thin film transistor array panel and a method for manufacturing the same.

(b) Description of the Related Art

Liquid crystal display (LCD), plasma display panel (PDP), and organic light emitting device (OLED) are among widely used flat panel displays today.

Plasma display panel is a display device for displaying characters or images by using plasma generated by gas discharge. In an organic light emitting device, electrons and holes are injected into an organic illumination layer respectively from a cathode (a electron injection electrode) and an anode (a hole injection electrode). The injected electrons and holes are combined to generate excitons, which emit light when an electron transitions an excited state to a ground state. The LCD is a display device using electro-optical characteristics of liquid crystals in which light transmission amounts are varied according to the intensity of an applied electric field to thereby realize the display of images.

Among these flat panel displays, LCD and OLED include switching elements connected to field generating electrodes, and a plurality of signal lines such as gate lines and data lines to apply voltages to the field generating electrodes by controlling the switching elements. To reduce an afterimage of the display device and to improve the resolution, it is preferable that the resistance of the signal lines is low.

Particularly, according to the increasing of the size of the display devices, a more improved response speed is required to obtain high quality, and research to reduce resistance of the signal lines has made much progressed.

### SUMMARY OF THE INVENTION

A thin film transistor array panel according to an exemplary embodiment of the present invention includes a substrate, a light blocking member formed on the substrate and including a first furrow and a receiving portion, a gate line disposed on the first furrow, a semiconductor layer disposed on the gate line, a data line and a drain electrode formed on the semiconductor layer, and a pixel electrode connected to the drain electrode.

The gate line may include an upper layer and a lower layer, and the upper layer may include copper. The lower layer may include a material selected from the group of molybdenum, a molybdenum alloy, titanium, and combinations thereof.

The depth of the first furrow may be in a range of 1 μm to 2 μm.

The light blocking member may further include a second furrow, and the data line and the drain electrode are disposed in the second furrow.

The depth of the second furrow may be less than the depth of the first furrow.

The first furrow, the second furrow, or both furrows may extend to the substrate.

The thin film transistor array panel may further include a color filter disposed in the receiving portion.

The height of a surface on the plane boundary of the color filter may be equal to or less than the height of the light blocking member.

The thin film transistor array panel may further include a gate insulating layer formed on the substrate and the gate line, wherein the color filter is disposed on the gate insulating layer or between the gate line and the gate insulating layer.

The thin film transistor array panel may further include a passivation layer disposed on the color filter, the semiconductor layer, the data line, and the drain electrode.

A thin film transistor array panel according to an exemplary embodiment of the present invention includes a substrate, a light blocking member formed on the substrate and having a data furrow, a gate line formed on the substrate, a semiconductor layer formed on the gate line, a data line disposed in the data furrow, a passivation layer formed on the semiconductor layer and the data line, and a pixel electrode formed on the passivation layer and receiving data voltages from the data line.

The data line may include an upper layer and a lower layer, and the upper layer includes copper. The data furrow may extend to the substrate.

A method for manufacturing a thin film transistor array panel according to an exemplary embodiment of the present invention includes forming a photosensitive film on a substrate, exposing and developing the photosensitive film to form a light blocking member having a first furrow, a second furrow, and a receiving portion, forming a lower layer of a gate line in the first furrow, forming an upper layer of the gate line on the lower layer, forming a gate insulating layer on the substrate and the upper layer of the gate line, forming a semiconductor layer on the gate insulating layer, forming a data line and a drain electrode in the second furrow, and forming a pixel electrode connected to the drain electrode.

The first furrow and the second furrow may be formed by using slit exposure.

The lower layer of the gate line may be formed by sputtering. The upper layer of the gate line may be formed by electroless plating or electroplating.

The formation of the data line and the drain electrode may include depositing a metal layer in the second furrow by sputtering to form the lower layer of the data line and the drain electrode, and forming an upper layer of the data line and the drain electrode on the lower layer.

The upper layer of the data line and the drain electrode may be formed by electroless plating or electroplating.

The photosensitive film may have positive photosensitivity.

The method may further include forming a color filter in the receiving portion.

The color filter may be disposed on the gate insulating layer, or the color filter may be disposed between the substrate and the gate insulating layer.

According to an exemplary embodiment of the present invention, the furrow of the light blocking member is formed by using a slit process such that it is necessary to additionally form the furrow in the substrate or in gate insulating layer, and the gate line and the data line are formed in the furrow of the light blocking member such that a misalignment thereof may be prevented.

The thickness of the gate line or the data line made of copper is designed by controlling the furrow depth of the light blocking member such that resistance thereof may be reduced.

The data line and the pixel electrode are separated from each other by the light blocking member such that parasitic capacitance generated therebetween may be reduced.

When forming the color filter by using an Inkjet method, the light blocking member is used as a bank such that an additional process to form the bank is not necessary

Accordingly, the manufacturing process of the thin film transistor array panel may be simplified, the manufacturing cost may be reduced, and productivity thereof may be improved.

### BRIEF DESCRIPTION OF THE DRAWINGS

An exemplary embodiment of the present invention will be described in detail with reference to the accompanying drawings for clear understanding of advantages of the present invention, wherein:

FIG. 1 is a layout view of a thin film transistor array panel according to an exemplary embodiment of the present invention;

FIG. 2 is a cross-sectional view of the thin film transistor array panel shown in FIG. 1 taken along the line II-II;

FIG. 3 is an enlarged view of an A portion of FIG. 2;

FIG. 4 is an enlarged view of a B portion of FIG. 2;

FIG. 5 and FIG. 6 are cross-sectional views of thin film transistor array panels according to another exemplary embodiment of the present invention; and

FIG. 7 to FIG. 13 are cross-sectional views sequentially showing the thin film transistor array panel in the manufacturing process of the thin film transistor array panel.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

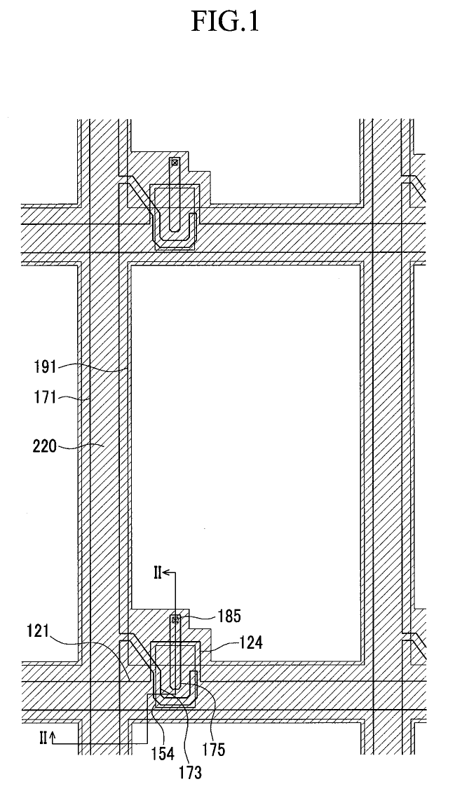

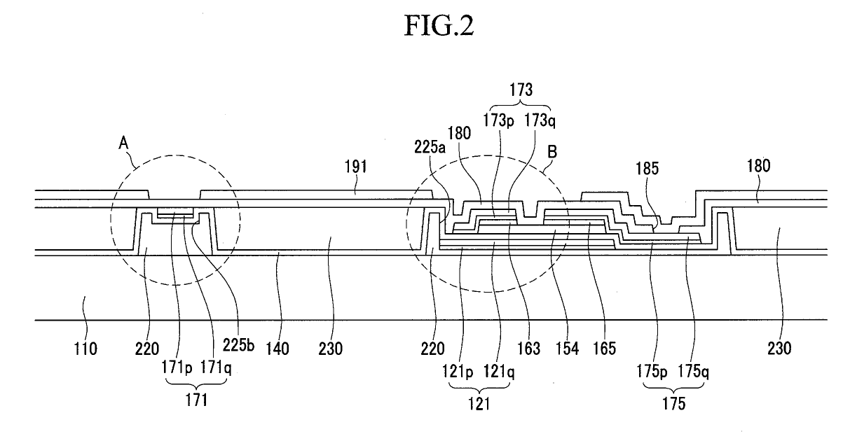

Now, a display panel according to an exemplary embodiment of the present invention will be described in detail with reference to FIG. 1 to FIG. 2.

FIG. 1 is a layout view of a thin film transistor array panel according to an exemplary embodiment of the present invention, and FIG. 2 is a cross-sectional view of the thin film transistor array panel shown in FIG. 1 taken along the line II-II.

Referring to FIG. 1 and FIG. 2, a light blocking member 220 is formed on a substrate 110 made of an insulating material such as glass or plastic. The light blocking member 220 may be made of an organic material having positive photosensitivity or negative photosensitivity. The light blocking member 220 includes furrows 225a and 225b extending in horizontal and vertical directions and a plurality of receiving portions 227 arranged in a matrix shape. The furrows 225a extending in the horizontal direction (hereinafter referred to as “horizontal direction furrow”) and the furrows 225b extending in the vertical direction (hereinafter referred to as “vertical direction furrow”) respectively include portions protruding with reference to the horizontal and vertical directions. The horizontal direction furrow 225a is a furrow for forming a gate line 121, a portion of a source electrode 173 of a data line 171, and a drain electrode 175, and the vertical direction furrow 225b is a furrow that may be used as a data furrow for forming a data line.

The depth of the furrows 225a and 225b is in a range of about 0.3 μm to 2 μm. The depths of the horizontal direction furrow 225a and the vertical direction furrow 225b are different from each other. However, the depths of the horizontal and vertical direction furrow 225a and 225b may be the same. One side surface of the light blocking member 220 defining the receiving portion 227 has a step. In plan view, the shape of the receiving portion 227 may be any suitable shape such as a quadrangle.

A plurality of gate lines 121 are formed in the horizontal direction furrows 225a of the light blocking member 220. In plan view, the gate lines 121 transmit gate signals and each of the gate lines 121 includes a plurality of gate electrodes 124. The gate lines 121 may have almost the same shape as the horizontal direction furrows 225a.

The gate lines 121 have a dual-layered structure including a lower layer 121p and an upper layer 121q.

The upper layer 121q may be made of copper (Cu) by using electroless plating. The lower layer 121p may be made of a metal such as molybdenum (Mo), titanium (Ti), or a molybdenum alloy such as MoN, MoTi, MoZr, and MoNb. The lower layer 121p made of the above-described material has good physical, chemical, and electrical contact characteristics with other materials, and particularly the electroless plating of the copper thereon becomes easy. On the other hand, the upper layer 121q may be made of copper by using an electroplating method.

In another embodiment, the gate lines 121 may have a single-layered structure.

A gate insulating layer 140, which is preferably made of silicon nitride (SiNx) or silicon oxide (SiOx), is formed on the substrate 110 and the gate lines 121, and in the vertical direction furrows 225b.

A plurality of semiconductor islands 154, a plurality of ohmic contacts 163 and 165, and a gate insulating layer 140 are sequentially formed thereon. They overlap the gate electrodes 124 and are disposed in the horizontal direction furrows 225a. The semiconductors 154 may be made of a material such hydrogenated amorphous silicon or polysilicon. The ohmic contacts 163 and 165 may be made of amorphous silicon doped with an impurity of a high concentration, or of polysilicon.

A plurality of data lines 171 and a plurality of drain electrode 175 are formed on the gate insulating layer 140 and the ohmic contacts 163 and 165. The data lines 171 transmit data signals and each of the data lines 171 includes a plurality of source electrodes 173 extending toward the gate electrodes 124. The drain electrode 175 is separated from the data line 171 and the gate electrode 124 is formed between the source electrode 173 and the drain electrode 175 while partially overlapping both electrodes 173, 175. The semiconductors 154 include a portion formed between the source electrodes 173 and the drain electrodes 175.

The surfaces of the data line 171 and the drain electrode 175 may be disposed inside the furrows 225a and 225b, or may be higher than the furrows 225a and 225b.

The ohmic contacts 163 and 165 disposed under the data lines 171 and the drain electrodes 175 reduce the contact resistance between the semiconductor layers 154 and the data lines 171 and drain electrodes 175.

Like the gate lines 121, the data lines 171 and the drain electrodes 175 have a dual-layered structure including lower layers 171p and 175p and upper layers 171q and 175q.

The upper layers 171q and 175q of the data lines 171 and the drain electrodes 175 may be made by using electroless plating or electroplating. The upper layers 171q and 175q and the lower layers 171p and 175p may be respectively made of the same material as that of the upper layer 121q and the lower layer 121p and by using the same method. However, the data lines 171 may have a single-layered structure.

In FIG. 2, the source electrode 173 includes a lower layer 173p and an upper layer 173q.

The data lines 171 and drain electrodes 175 may have substantially the same shape as the ohmic contacts 163 and 165.

One gate electrode 124, one source electrode 173, and one drain electrode 175 constitute one thin film transistor (TFT) along with the semiconductor 154. The channel of the thin film transistor Q is formed in the semiconductors 154 between the source electrode 173 and the drain electrode 175.

A plurality of color filters 230 are formed on the gate insulating layer 140.

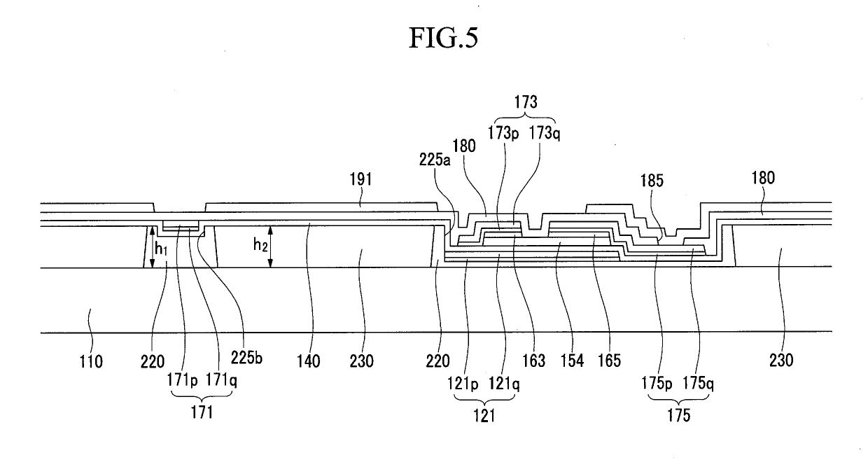

The color filters 230 are disposed in the receiving portions 227 of the light blocking member 220. The value of the height of the color filters 230 may be equal to or less than the value of the height of the light blocking member 220. The color filters 230 may display one of primary colors such as three primary colors of red, green, and blue, and may be made of an organic material. However, as shown in FIG. 5, the color filters 230 may be formed between the substrate 110 and the gate insulating layer 140.

A passivation layer 180 is formed on the data lines 171, the drain electrodes 175, and the color filters 230. The passivation layer 180 is made of an inorganic insulator such as silicon nitride (SiNₓ) or silicon oxide (SiOx). Also, the passivation layer 180p may have a dual-layered structure of an inorganic layer and an organic layer so as to not cause damage to the exposed portions of the semiconductors 154 while maintaining the excellent insulating characteristics of the organic layer. The passivation layer 180 has a plurality of contact holes 185 exposing the drain electrodes 175.

A plurality of pixel electrodes 191 are formed on the passivation layer 180. They may be made of a transparent conductive material such as ITO or IZO. The pixel electrodes 191 are connected to the drain electrodes 175 through the contact holes 185.

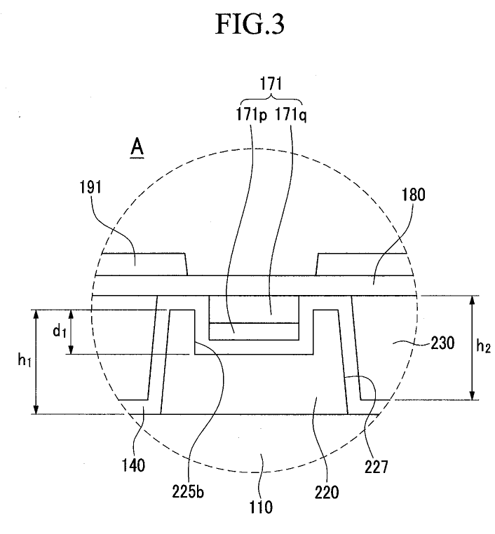

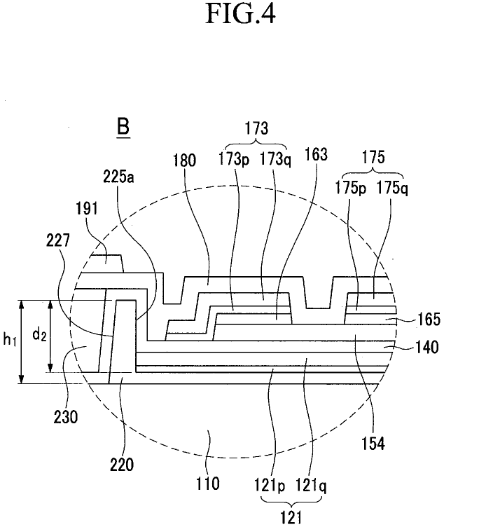

Next, the depths of the furrows 225a and 225b of the light blocking member 220 and the height of the color filters 230 will be described in detail with reference to FIG. 3 and FIG. 4.

FIG. 3 is an enlarged view of an A portion of FIG. 2, and FIG. 4 is an enlarged view of a B portion of FIG. 2.

Referring to FIG. 3, the depth d₁ of the vertical direction furrow 225b of the light blocking member 220 may be in a range of about 0.3 μm to 1 μm. The gate insulating layer 140 and the data line 171 are disposed in the vertical direction furrow 225b. The upper surface of the data line 171 is the same plane shape as the upper surface of the gate insulating layer 140 disposed on the light blocking member 220. However, the upper surface of the data line 171 may be lower than the upper surface of the gate insulating layer 140 such that the upper surface of the data line 171 may be the same plane shape as the upper portion of the light blocking member 220 or may be disposed in the vertical direction furrow 225b. The upper surface of the data line 171 may be higher than the upper surface of the gate insulating layer 140.

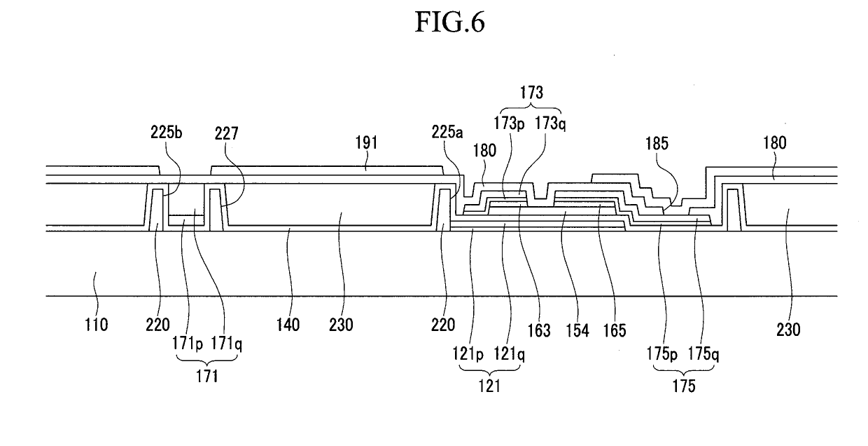

The height h1 of the light blocking member 220 has a larger value than the depth d1 of the vertical direction furrow 225b. However, as shown in FIG. 6, the vertical direction furrow 225b exposes the substrate 110, and the height of the light blocking member 220 may be equal to the depth of the vertical direction furrow 225b.

Referring to FIG. 4, the depth d2 of the horizontal direction furrow 225a of the light blocking member 220 may be in a range of about 1 μm to 2 μm. The gate line 121, the gate insulating layer 140, the semiconductor layer 154, the ohmic contacts 163 and 165, the data line 171, and the drain electrode 175 are disposed in the horizontal direction furrow 225a. The height h1 of the light blocking member 220 may have a larger value than the depth d2 of the horizontal direction furrow 225a, and as shown in FIG. 6, when the horizontal direction furrow 225a extends to the substrate 110, the height of the light blocking member 220 and the depth of the horizontal direction furrow 225a may be equal to each other.

More of the gate line 121 and the semiconductor layer 154 are formed in the horizontal direction furrow 225a of the light blocking member 220 than the vertical direction furrow 225b such that the depth d₂ of the horizontal direction furrow 225a is larger than the depth d₁ of the vertical direction furrow 225b. Accordingly, the upper surface of the source electrode 173 and the drain electrode 175 are disposed on the light blocking member 220 and may be disposed on the same plane surface as the upper surface of the gate insulating layer 140. However, the upper surface of the source electrode 173 and the drain electrode 175 is lower than the upper surface of the gate insulating layer 140 such that the upper surface of the source electrode 173 and the drain electrode 175 does not deviate from the horizontal direction furrow 225a or may be higher than the upper surface of the gate insulating layer 140.

Again referring to FIG. 3 and FIG. 4, the color filters 230 are disposed in the receiving portions 227 of the light blocking member 220. The surface height h2 on the plane boundary of the color filter 230 has the same value as the height h1 of the light blocking member 220. That is to say, the sum value of the height h2 of the color filter 230 and the thickness of the gate insulating layer 140 disposed thereunder is substantially the same as the sum value of the height h1 of the light blocking member 220 and the thickness of the gate insulating layer 140 disposed thereunder. However, the height h2 of the color filter 230 may have a less or larger value than the height h1 of the light blocking member 220. In the case of FIG. 5, the height of the color filter 230 formed between the substrate 110 and the gate insulating layer 140 may be equal to or less than the height h1 of the light blocking member.

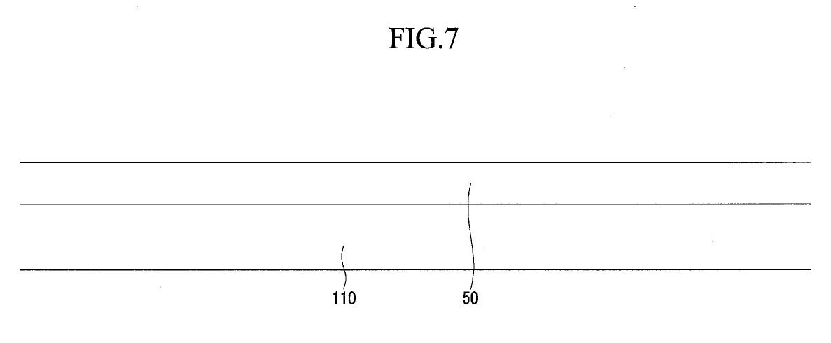

Next, a manufacturing method of the thin film transistor array panel of FIG. 1 and FIG. 2 will be described with reference to FIG. 7 to FIG. 13 as well as FIG. 1 and FIG. 2.

FIG. 7 to FIG. 13 are cross-sectional views sequentially showing the thin film transistor array panel in the manufacturing process of the thin film transistor array panel.

As shown in FIG. 7, an organic material having positive photosensitivity is coated on a substrate 110 to form a photosensitive film 50. However, the organic material may have negative photosensitivity.

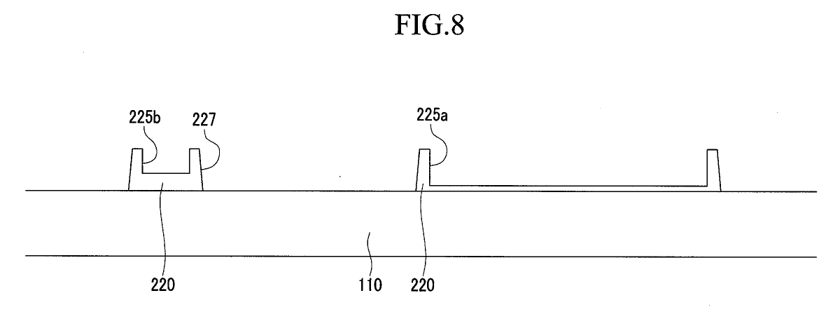

Next, as shown in FIG. 8, the photosensitive film 50 is exposed and developed to form a light blocking member 220 having horizontal and vertical direction furrows 225a and 225b and receiving portions 227. A portion of the photosensitive film 50 irradiated by the light is removed such that it is easy to control the depth of the horizontal and vertical direction furrows 225a and 225b, and the receiving portions 227. Here, the horizontal and vertical direction furrows 225a and 225b may be formed by using slit exposure. The horizontal and vertical direction furrows 225a and 225b have different depths. However, the horizontal and vertical direction furrows 225a and 225b may have the same depth in some embodiments. Furthermore, the substrate 110 may be exposed at this stage of manufacturing.

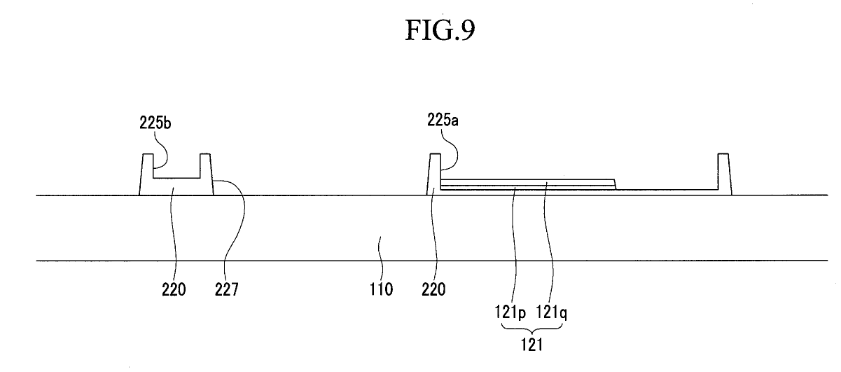

Next, as shown in FIG. 9, a metal such as molybdenum is deposited in the horizontal direction furrows 225a by sputtering to form lower layers 121p of gate lines 121. The metal is sputtered while blocking the portion except for the horizontal direction furrows 225a by using a mask such that the lower layers 121p are only formed in the horizontal direction furrows 225a. Next, copper is formed by electroless plating to form upper layers 121q of the gate lines 121. Here, the lower layers 121p function as a seed layer for the copper. The upper layers 121q of the gate lines 121 may be made by electroplating. The thickness of the gate lines 121 may be designed by controlling the depth of the horizontal direction furrows 225a.

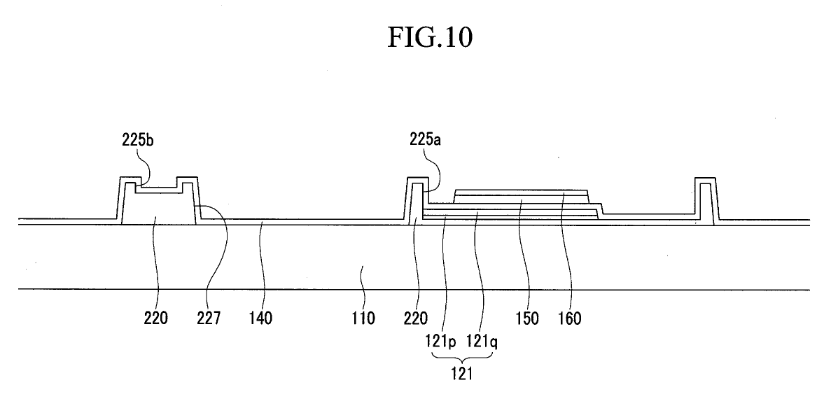

Next, as shown in FIG. 10, a gate insulating layer 140 is formed on the substrate 110, the gate lines 121, and the furrows 225a and 225b. A semiconductor layer 154 and ohmic contacts 163 and 165 are then sequentially formed on the gate insulating layer 140.

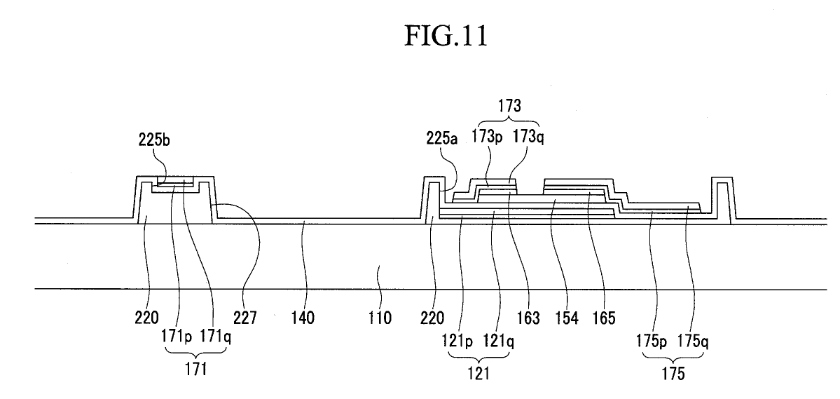

As shown in FIG. 11, data lines 171 including source electrodes 173 and drain electrodes 175 are formed on the gate insulating layer 14 disposed on the furrows 225a and 225b, the semiconductor layers 154, and the ohmic contacts 163 and 165. The data lines 171 and the drain electrodes 175 are made of the same dual-layered structure as the gate lines 121, and the method for manufacturing them is substantially the same as the method for manufacturing the gate lines 121.

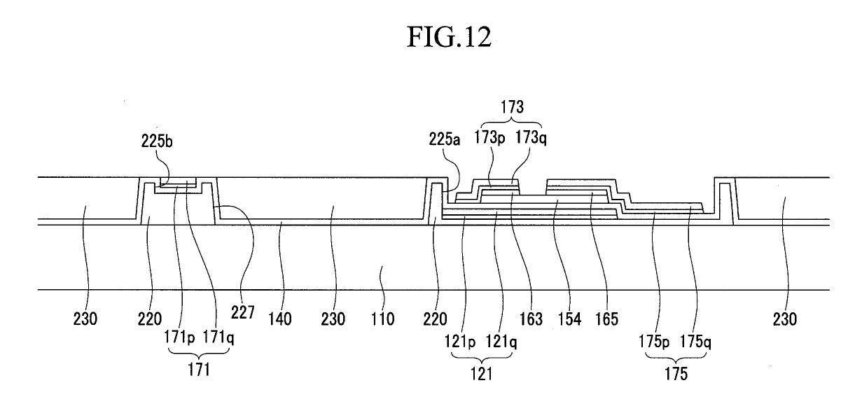

Next, as shown in FIG. 12, an organic material solution including pigments is deposited in the receiving portions 227 of the light blocking member 225 by using an Inkjet method and dried to form color filters 230. Here, the light blocking member 220 functions as a bank such that the required amount of the organic material solution to form the color filters 230 is controlled to determine the height of the light blocking member 220. The surface of the organic material solution is disposed on the same plane surface of the gate insulating layer 140 disposed on the light blocking member 220, and may be lower. In the present exemplary embodiment, the light blocking member 220 is used as the bank such that it is not necessary to form an additional bank for forming the color filters 230. Accordingly, the manufacturing process of the thin film transistor array panel may be simplified and the manufacturing cost may be reduced.

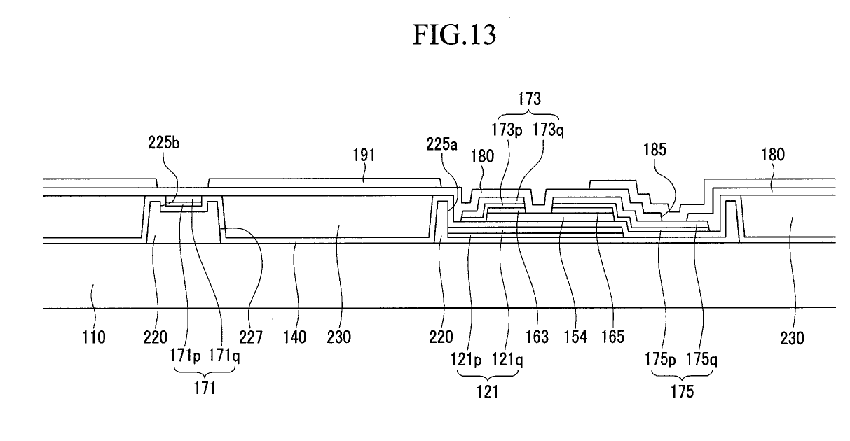

Next, as shown in FIG. 13, a passivation layer 180 of silicon nitride or silicon oxide is deposited and patterned to form contact holes 185. Pixel electrodes 191 are then formed on the passivation layer 180. The pixel electrodes 191 are separated from the data lines 171 by the light blocking member 220.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel comprising:
a substrate;
a light blocking member formed on the substrate and including a first furrow and a receiving portion;
a gate line disposed on the first furrow;
a semiconductor layer disposed on the gate line;
a data line and a drain electrode formed on the semiconductor layer; and
a pixel electrode connected to the drain electrode.

2. The thin film transistor array panel of claim 1, wherein
the gate line comprises an upper layer and a lower layer, and the upper layer includes copper.

3. The thin film transistor array panel of claim 2, wherein
the lower layer comprises a material selected from the group consisting of molybdenum, a molybdenum alloy, titanium, and combinations thereof.

4. The thin film transistor array panel of claim 1, wherein
the depth of the first furrow is in a range of 1 μm to 2 μm.

5. The thin film transistor array panel of claim 4, wherein
the light blocking member further comprises a second furrow, and
the data line and the drain electrode are disposed in the second furrow.

6. The thin film transistor array panel of claim 5, wherein
the depth of the second furrow is less than the depth of the first furrow.

7. The thin film transistor array panel of claim 5, wherein at least one of the first furrow and the second furrow extends to the substrate.

8. The thin film transistor array panel of claim 1, further comprising a color filter disposed in the receiving portion.

9. The thin film transistor array panel of claim 8, wherein
the height of a surface on the plane boundary of the color filter is equal to or less than the height of the light blocking member.

10. The thin film transistor array panel of claim 8, further comprising
a gate insulating layer formed on the substrate and the gate line,
wherein the color filter is disposed on the gate insulating layer or between the gate line and the gate insulating layer.

11. The thin film transistor array panel of claim 8, further comprising
a passivation layer disposed on the color filter, the semiconductor layer, the data line, and the drain electrode.

12. A thin film transistor array panel comprising:
a substrate;
a light blocking member formed on the substrate and having a data furrow;
a gate line formed on the substrate;
a semiconductor layer formed on the gate line;
a data line disposed in the data furrow;
a passivation layer formed on the semiconductor layer and the data line; and
a pixel electrode formed on the passivation layer and receiving data voltages from the data line.

13. The thin film transistor array panel of claim 12, wherein
the data line comprises an upper layer and a lower layer, and the upper layer comprises copper.

14. The thin film transistor array panel of claim 12, wherein
the data furrow extends to the substrate.

15. A method for manufacturing a thin film transistor array panel, comprising:
forming a photosensitive film on a substrate;
exposing and developing the photosensitive film to form a light blocking member having a first furrow, a second furrow, and a receiving portion;
forming a lower layer of a gate line in the first furrow;
forming an upper layer of the gate line on the lower layer;
forming a gate insulating layer on the substrate and the upper layer of the gate line;
forming a semiconductor layer on the gate insulating layer;
forming a data line and a drain electrode in the second furrow; and
forming a pixel electrode connected to the drain electrode.

16. The method of claim 15, wherein
the first furrow and the second furrow are formed by using slit exposure.

17. The method of claim 16, wherein
the lower layer of the gate line is formed by sputtering.

18. The method of claim 17, wherein
the upper layer of the gate line is formed by electroless plating or electroplating.

19. The method of claim 15, wherein the formation of the data line and the drain electrode comprises
depositing a metal layer in the second furrow by sputtering to form the lower layer of the data line and the drain electrode, and
forming an upper layer of the data line and the drain electrode on the lower layer.

20. The method of claim 19, wherein
the upper layer of the data line and the drain electrode is formed by electroless plating or electroplating.

21. The method of claim 15, wherein
the photosensitive film has positive photosensitivity.

22. The method of claim 15, further comprising
forming a color filter in the receiving portion.

23. The method of claim 22, wherein
the color filter is disposed on the gate insulating layer.

24. The method of claim 22, wherein
the color filter is disposed between the substrate and the gate insulating layer.
